(19) United States
(12) Patent Application Publication
(10) Pub. No.: US 2022/0363834 A1
(43) Pub. Date: Nov. 17, 2022

(54) THERMALLY CONDUCTIVE SILICONE COMPOSITION AND METHOD FOR PRODUCING THE SAME

(71) Applicant: Fuji Polymer Industries Co., Ltd., Nagoya-shi, Aichi (JP)

(72) Inventors: Makoto IWAI, Aichi (JP); Shingo KOBAYASHI, Aichi (JP); Yuko KIMURA, Aichi (JP)

(21) Appl. No.: 17/633,753

(22) PCT Filed: Apr. 2, 2021
(86) PCT No.: PCT/JP2021/014304

§ 371 Date: Feb. 8, 2022

(30) Foreign Application Priority Data
Sep. 3, 2020 (JP) 2020-148460

(51) Int. Cl. C08G 77/04; C08K 3/22; C08K 9/06; C08K 9/08; H01L 23/373

(52) U.S. Cl. CPC C08G 77/04; C08K 3/22; C08K 9/06; C08K 9/08; H01L 23/3737; C08K 2003/2227; C08K 2201/001

(57) ABSTRACT

A thermally conductive silicone composition contains a silicone polymer and a thermally conductive inorganic filler. The thermally conductive inorganic filler is surface treated with a first surface treatment agent and further surface treated with a second surface treatment agent. The first surface treatment agent contains an organic silane compound represented by R¹¹SiR¹²ₓ(OR¹³)₃₋ₓ (where R¹¹ is, e.g., a monovalent aliphatic hydrocarbon group having 1 to 18 carbon atoms, a monovalent aromatic hydrocarbon group having 6 to 30 carbon atoms, or a hydrocarbon group having an alkoxysilyl group, R¹² is, e.g., a methyl group, and R¹³ is, e.g., a hydrocarbon group having 1 to 4 carbon atoms). The second surface treatment agent contains a silicone polymer that has a kinematic viscosity of 10 to 1000 mm²/s and does not have a hydrolyzable group. Thus, the present invention provides a thermally conductive silicone composition that has a low slurry viscosity and achieves high extrudability and high moldability, and a method for producing the thermally conductive silicone composition.

### TECHNICAL FIELD

The present invention relates to a thermally conductive silicone composition that is suitable to be interposed between a heat generating member and a heat dissipating material of electrical and electronic components or the like, and a method for producing the thermally conductive silicone composition.

### BACKGROUND ART

With the significant improvement in performance of semiconductor devices such as CPUs in recent years, the amount of heat generated by them has become extremely large. For this reason, heat dissipating materials are attached to electronic components such as semiconductor devices that may generate heat, and a thermally conductive silicone grease or sheet is used to improve the adhesion between the heat dissipating materials and the semiconductor devices. Patent Document 1 proposes a method for treating the surface of a thermally conductive inorganic filler with a silane coupling agent having along chain alkyl group in order to reduce an increase in the viscosity of a slurry that is obtained by mixing the filler and abase polymer, and to improve extrudability and moldability. However, if the filler is composed of particles with a large specific surface area and a small particle diameter, it may not be sufficient to simply treat such a filler with the silane coupling agent having along chain alkyl group in terms of preventing an increase in the viscosity of the slurry. Therefore, a further reduction in the viscosity of the slurry is desirable to improve extrudability and processability. Patent Documents 2 to 4 propose, as a solution to this problem, the use of a polymeric coupling agent to enhance the affinity between the surface of a filler and a polymer.

### PRIOR ART DOCUMENTS

### Patent Documents

Patent Document 1: JP 3092127 B2
Patent Document 2: JP H10(1998)-045857 A
Patent Document 3: JP 2000-256558 A
Patent Document 4: JP 2009-221210 A

### DISCLOSURE OF INVENTION

### Problem to be Solved by the Invention

However, when the conventional polymeric surface treatment agent having a large molecular weight is in contact with an inorganic filler composed of particles with a large specific surface area and a small average particle size, the wettability of the surface of the inorganic filler can be reduced. Thus, the reactivity of the polymeric surface treatment agent with the surface of the inorganic filler may be poor. Moreover, a hydrolyzable functional group that does not react with the surface of the inorganic filler remains in the polymeric surface treatment agent and may have an adverse effect on the physical properties of a composite material produced by molding the mixture. As a result, in the conventional technology, the slurry viscosity is high, and both extrudability and moldability are unsatisfactory.

To solve the above conventional problems, the present invention provides a thermally conductive silicone composition that has a low slurry viscosity and achieves high extrudability and high moldability by incorporating a thermally conductive inorganic filler that has been subjected to a multiple surface treatment, and a method for producing the thermally conductive silicone composition.

### Means for Solving Problem

A thermally conductive silicone composition of the present invention contains a silicone polymer as a matrix resin and a thermally conductive inorganic filler. The thermally conductive inorganic filler is surface treated with a first surface treatment agent and further surface treated with a second surface treatment agent. The first surface treatment agent contains an organic silane compound represented by R¹¹SiR¹²ₓ(OR¹³)₃ (where R¹¹ is a monovalent aliphatic hydrocarbon group having 1 to 18 carbon atoms, a monovalent aromatic hydrocarbon group having 6 to 30 carbon atoms, or a monovalent substituent represented by the following Chemical Formula (1), Chemical Formula (2), Chemical Formula (3), or Chemical Formula (4):

[Chemical Formula 1] R¹⁴_{y}R¹⁵_{3-y}SiOR¹⁶(CₙH₂ₙ)ₚ (1);

[Chemical Formula 2] [(R¹³O)_{3-z}R¹²_{z}Si](CₙH₂ₙ)ₚR¹⁶(CₙH₂ₙ)ₚ (2);

[Chemical Formula 3] [(R¹³O)_{3-z}R¹²_{z}SiO]R¹⁶ (3);

[Chemical Formula 4] [(R¹³O)_{3-z}R¹²_{z}Si]R¹⁷ (4),

R¹² is a methyl group or a phenyl group and may be the same or different, R¹³ is a hydrocarbon group having 1 to 4 carbon atoms and may be the same or different, R¹⁴ is a hydrocarbon group having 1 to 4 carbon atoms or a phenyl group and may include a double bond, R¹⁵ is a methyl group or a phenyl group, R¹⁶ is a divalent polysiloxane represented by (R¹⁸₂SiO)ₘ, R¹⁷ is a divalent aliphatic hydrocarbon group having 1 to 18 carbon atoms or a divalent aromatic hydrocarbon group having 6 to 30 carbon atoms, R¹⁸ is at least one selected from a methyl group and a phenyl group, x is 1 to 2, y is 1 to 3, z is 0 to 3, n is an integer of 1 to 4, mis an integer of 1 to 20, and p is 0 or 1). The second surface treatment agent contains a silicone polymer that has a kinematic viscosity of 10 to 1000 mm²/s and does not have a hydrolyzable group.

A method for producing a thermally conductive silicone composition of the present invention provides the thermally conductive silicone composition as described above. The method includes the following: surface treating the thermally conductive inorganic filler with a first surface treatment agent containing an organic silane compound represented by R¹¹SiR¹²(OR¹³)₃₋ₓ(where R¹¹, R¹², and R¹³ are the same as defined above); surface treating the thermally conductive inorganic filler with a second surface treatment agent containing a silicone polymer that has a kinematic viscosity of 10 to 1000 mm²/s and does not have a hydrolyzable group; and mixing the silicone polymer as the matrix resin and the thermally conductive inorganic filler that has been surface treated with the first surface treatment agent and the second surface treatment agent, and optionally curing the mixture.

### Effects of the Invention

The thermally Conductive silicone composition of the present invention contains the thermally conductive inorganic filler that is surface treated with the first surface treatment agent, which is a silane coupling agent having good reactivity with the surface of the filler, and further surface treated with the second surface treatment agent containing a silicone polymer that has a kinematic viscosity of 10 to 1000 mm % and does not have a hydrolyzable group. This configuration can reduce the slurry viscosity and improve the extrudability and moldability of the thermally conductive silicone composition.

### DESCRIPTION OF THE INVENTION

The present inventors performed a multiple surface treatment on a thermally conductive inorganic filler (also referred to as an inorganic filler or inorganic particles in the following). Specifically, the thermally conductive inorganic filler was first surface treated with a silane coupling agent having good reactivity with the surface of the filler (i.e., the first surface treatment), and further surface treated with a curable or non-curable silicone polymer that has a kinematic viscosity of 10 to 1000 mm²/s and does not have a hydrolyzable group (i.e., the second surface treatment). Then, the present inventors found that the thermally conductive silicone composition containing a silicone polymer as a matrix resin and the inorganic filler thus treated had distinctive features such as a low slurry viscosity, high extrudability, and high moldability. Moreover, it was confirmed that the multiple surface treatment was significantly effective particularly for a thermally conductive filler composed of particles with a large specific surface area and a small particle diameter. In the context of the present invention, the multiple surface treatment means a plurality of surface treatments.

The first surface treatment agent of the present invention contains an organic silane compound represented by R¹¹SiR¹²ₓ(OR¹³)₃₋ₓ (where R¹¹, R¹², and R¹³ are the same as defined above) or an organic silane compound containing organic siloxane. The organic silane compound and the organic silane compound containing organic siloxane are also referred to as a silane coupling agent.

Examples of the silane coupling agent include the following: methyltrimethoxysilane; ethyltrimethoxysilane; propyltrimethoxysilane; butyltrimethoxysilane; pentyltrimethoxysilane; hexyltrimethoxysilane; hexyltriethoxysilane; octyltrimethoxysilane; octyltriethoxysilane; decyltrimethoxysilane; decyltriethoxysilane; dodecyltrimethoxysilane; dodecyltriethoxysilane; hexadecyltrimethoxysilane; hexadecyltriethoxysilane; octadecyltrimethoxysilane; octadecyltriethoxysilane; vinyltrimethoxysilane; vinyltriethoxysilane; allyltrimethoxysilane; hexenyltrimethoxysilane; octenyltrimethoxysilane; phenyltrimethoxysilane; phenylethyltriethoxysilane; phenylpropyltrimethoxysilane; styryltrimethoxysilane; styrylethyltriethoxysilane; naphthyltrimethoxysilane; anthracenyltrimethoxysilane; bis(trimethoxysilyl)benzene; bis(trimethoxysilyl)hexane; bis(trimethoxysilyl)octane; polysiloxane oligomer having trimethoxysilyl at both ends; polysiloxane oligomer having timethoxysilyl at one end; and polydimethylsioxane oligomer having trimethoxysilylethyl at one end. These silane coupling agents may be used individually or in combinations of two or more. In this case, the surface treatment may include adsorption in addition to a covalent bond. R¹¹ of the first surface treatment agent is preferably, e.g., an aliphatic hydrocarbon group having 1 to 18 carbon atoms, an aromatic hydrocarbon group having 6 to 30 carbon atoms, a trialkoxysilylalkyl group in which the carbon number of the alkyl group is 1 to 18, a monovalent alkylsiloxane oligomer in which the average degree of polymerization of siloxane is 20 or less, or an alkoxysilylsiloxane oligomer with an average degree of polymerization of 20 or less. This allows the first surface treatment agent to be highly reactive with the surface of the inorganic filler.

The first surface treatment with the silane coupling agent is preferably a dry treatment using a high-speed stirrer such as a Henschel mixer, in which the inorganic filler is loaded and subsequently the first surface treatment agent is added and mixed together. Alternatively, the first surface treatment may be a wet treatment. In the wet treatment, the inorganic filler, the first surface treatment agent, and a solvent are mixed to form a slurry, from which the solvent is then evaporated and removed. In this case, the dry treatment is suitable because of its simple operation. Moreover, heating and decompression may be performed simultaneously in the surface treatment by high speed rotation. In the dry treatment, the silane coupling agent is applied preferably in an amount of 0.1 to 20 parts by mass, and more preferably in an amount of 0.5 to 10 parts by mass with respect to 100 parts by mass of the thermally conductive inorganic filler. The first surface treatment may further include a heating process at 80 to 180° C. for 1 to 24 hours in order to complete the treatment reaction.

The second surface treatment agent of the present invention is a silicone polymer that has a kinematic viscosity of 10 to 1000 mm²/s and does not have a hydrolyzable group. The kinematic viscosity is measured at 25° C. using an Ubbelohde viscometer, and described in, e.g., the manufacturer's catalog. Examples of the second surface treatment agent include the following: polydimethylsiloxane having vinyldimethylsilyl at both ends (kinematic viscosity: 350 mm²/s); poly(vinylmethyldimethyl)siloxane having trimethylsilyl at both ends (kinematic viscosity: 750 mm²/s); poly(phenylmethyldimethyl)polysiloxane (kinematic viscosity 125 mm²/s); and polydimethylsiloxane having dimethylhydrogensilyl at both ends (kinematic viscosity: 100 mm²/s).

The second surface treatment agent is applied preferably in an amount of 0.1 to 30 parts by mass, and more preferably in an amount of 1 to 20 parts by mass with respect to 100 parts by mass of the thermally conductive inorganic filler. This configuration can reduce the slurry viscosity and improve the extrudability and moldability of the thermally conductive silicone composition. The surface treatment with the second surface treatment agent is preferably a dry treatment using a high-speed stirrer such as a Henschel mixer. The second surface treatment may be performed subsequent to the first surface treatment in the same surface treatment device. Alternatively, the inorganic filler that has been subjected to the first surface treatment may be put in another device, to which the second surface treatment agent may be added. Moreover, heating and decompression may be performed simultaneously in the surface treatment by high speed rotation. The second surface treatment may further include a heating process at 80 to 180° C. for 1 to 24 hours in order to complete the treatment reaction. This heat treatment is desirable in terms of storage stability.

The thermally conductive silicone composition of the present invention contains the silicone polymer and the thermally conductive inorganic filler. The ratio X of a BET specific surface area to an average particle size of the thermally conductive inorganic filler is preferably 0.005 or more, which is represented by the following formula (1):

X=A_{BET}/d₅₀ (1)

where A_{BET} is the BET specific surface area (m²/g) and d₅₀ is the average particle size (μm) of the thermally conductive inorganic filler.

The ratio X of the BET specific surface area to the average particle size takes into account the unevenness of the surface of the thermally conductive inorganic filler. When X is 0.005 or more, the inorganic filler has a large specific surface area and a small average particle size. This makes the multiple surface treatment of the present invention more effective. X is preferably 500 or less, more preferably 0.005 to 100, and further preferably 0.01 to 50. The matrix resin and the silicone polymer of the second surface treatment agent may be the same or different. Two or more types of inorganic fillers with different X values may be used in combination. In such a case, the average of the X values is 0.005 or more.

The thermally conductive inorganic filler is preferably composed of inorganic particles of at least one selected from aluminum oxide, zinc oxide, magnesium oxide, aluminum nitride, boron nitride, and aluminum hydroxide. These inorganic fillers can improve the thermal conductive properties.

The content of the thermally conductive inorganic filler that has been subjected to the first surface treatment and the second surface treatment in the thermally conductive silicone composition is preferably 100 to 10000 parts by mass, more preferably 300 to 5000 parts by mass, and further preferably 500 to 900 parts by mass with respect to 100 parts by mass of the silicone polymer. This can improve the thermal conductive properties. The thermal conductivity is preferably 1 to 30 W/m·K, more preferably 1.2 to 10 W/m·K, and further preferably 1.5 to 5 W/m·K.

The thermally conductive silicone composition is preferably in the form of at least one selected from grease, putty, gel, and rubber. These materials are suitable as a TIM (thermal interface material) to be interposed between a heat generating member such as a semiconductor device and a heat dissipating material.

The method for producing the thermally conductive silicone composition of the present invention includes mixing the silicone polymer as the matrix resin and the thermally conductive inorganic filler that has been subjected to the first surface treatment and the second surface treatment, and optionally curing the mixture. The liquid materials such as grease and putty may not be cured. When a curing process is performed, a curing catalyst may be added. If the thermally conductive silicone composition is molded into, e.g., a sheet, a molding process is inserted between the mixing process and the curing process. The thermally conductive silicone composition in the form of a sheet is suitable for mounting on electronic components or the like. The thickness of the thermally conductive sheet is preferably 0.2 to 10 mm.

The surface treatment using the first surface treatment agent preferably includes a heating process at 80 to 180° C. for 1 to 24 hours, and further the surface treatment using the second surface treatment agent preferably includes a heating process at 80 to 180° C. for 1 to 24 hours. Due to these processes, the first surface treatment agent and the second surface treatment agent can be firmly fixed to the surface of the thermally conductive inorganic filler.

A compound with the following composition is preferably used to obtain a cured product.

A. Matrix Resin Component (Base Polymer)

The matrix resin component contains the following components A1 and A2. In this case, the components A1 and A2 add up to 100 parts by mass.

A1: a linear organopolysiloxane having at least two silicon-bonded alkenyl groups per molecule.

A2: an organohydrogenpolysiloxane having at least two silicon-bonded hydrogen atoms per molecule, which serves as a crosslinking component.

The number of moles of the organohydrogenpolysiloxane is 0.5 to 2.0 moles with respect to 1 mole of the alkenyl groups contained in the component A1, the first surface treatment agent, and the second surface treatment agent.

When the second surface treatment agent contains a silicon-bonded hydrogen atom, it is preferable that the amount of the silicon-bonded hydrogen atom is also included in the number of moles of the organohydrogenpolysiloxane, as calculated above.

The matrix resin component may contain an organopolysiloxane having no reactive group other than the components A1 and A2.

B. Thermally Conductive Inorganic Filler

The amount of the thermally conductive inorganic filler that has been subjected to the first surface treatment and the second surface treatment is 100 to 10000 parts by mass.

C. Curing Catalyst

When the curing catalyst is (1) an addition reaction catalyst that is a platinum-based metal catalyst, the amount of the addition reaction catalyst is 0.01 to 1000 ppm by mass with respect to the matrix resin component. When the curing catalyst is (2) an organic peroxide catalyst, the amount of the organic peroxide catalyst is 0.5 to 30 parts by mass with respect to the matrix resin component.

D. Other Additives

Other additives such as a curing retarder and a coloring agent may be added in any amount.

Hereinafter, each component will be described.

(1) Base Polymer Component (Component A1)

The base polymer component is an organopolysiloxane containing two or more alkenyl groups bonded to silicon atoms per molecule. The organopolysiloxane containing two or more alkenyl groups is the base resin (base polymer component) of a silicone rubber composition of the present invention. In this case, the organopolysiloxane has two silicon-bonded alkenyl groups per molecule. The alkenyl group has 2 to 8 carbon atoms, and particularly 2 to 6 carbon atoms and can be, e.g., a vinyl group or an allyl group. The viscosity of the organopolysiloxane is preferably 10 to 1000000 mPa·s, and more preferably 100 to 100000 mPa·s at 25° C. in terms of workability and curability.

Specifically, an organopolysiloxane represented by the following general formula (Chemical Formula 5) is used. This organopolysiloxane contains two or more alkenyl groups per molecule, in which the alkenyl groups are bonded to silicon atoms at both ends of the molecular chain. The organopolysiloxane is a linear organopolysiloxane whose side chains are capped with alkyl groups. The viscosity of the organopolysiloxane is preferably 10 to 1000000 mPa·s at 25° C. in terms of workability and curability. Moreover, the linear organopolysiloxane may include a small amount of branched structure (trifunctional siloxane units) in the molecular chain.

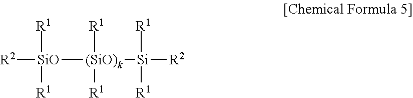

In the formula, R¹ represents substituted or unsubstituted monovalent hydrocarbon groups that are the same as or different from each other and have no aliphatic unsaturated bond, R² represents alkenyl groups, and k represents 0 or a positive integer. The monovalent hydrocarbon group represented by R¹ has, e.g., 1 to 10 carbon atoms, and more preferably 1 to 6 carbon atoms. Specific examples of the monovalent hydrocarbon group include the following: alkyl groups such as methyl, ethyl, propyl, isopropyl, butyl, isobutyl, tert-butyl, pentyl, neopentyl, hexyl, cyclohexyl, octyl, nonyl, and decyl groups; aryl groups such as phenyl, tolyl, xylyl, and naphthyl groups; aralkyl groups such as benzyl, phenylethyl, and phenylpropyl groups; and substituted forms of these groups in which some or all hydrogen atoms are substituted by halogen atoms (fluorine, bromine, chlorine, etc.) or cyano groups, including halogen-substituted alkyl groups such as chloromethyl, chloropropyl, bromoethyl, and trifluoropropyl groups and cyanoethyl groups. The alkenyl group represented by R² has, e.g., 2 to 6 carbon atoms, and more preferably 2 to 3 carbon atoms. Specific examples of the alkenyl group include vinyl, allyl, propenyl, isopropenyl, butenyl, isobutenyl, hexenyl, and cyclohexenyl groups. In particular, the vinyl group is preferred. In the general formula (Chemical Formula 5), k is typically 0 or a positive integer satisfying 0≤k≤10000, preferably 5≤k≤2000, and more preferably 10≤k≤1200.

The component A1 may also include an organopolysiloxane having three or more, typically 3 to 30, and preferably about 3 to 20, silicon-bonded alkenyl groups per molecule. The alkenyl group has 2 to 8 carbon atoms, and particularly 2 to 6 carbon atoms and can be, e.g., a vinyl group or an allyl group. The molecular structure may be a linear, ring, branched, or three-dimensional network structure. The organopolysiloxane is preferably a linear organopolysiloxane in which the main chain is composed of repeating diorganosiloxane units, and both ends of the molecular chain are capped with triorganosiloxy groups. The viscosity of the linear organopolysiloxane may be 10 to 1000000 mPa·s, and particularly 100 to 100000 mPa·s at 25° C.

Each of the alkenyl groups may be bonded to any part of the molecule. For example, the alkenyl group may be bonded to either a silicon atom that is at the end of the molecular chain or a silicon atom that is not at the end (but in the middle) of the molecular chain. In particular, a linear organopolysiloxane represented by the following general formula (Chemical Formula 6) is preferred. The linear organopolysiloxane has 1 to 3 alkenyl groups on each of the silicon atoms at both ends of the molecular chain. In this case, however, if the total number of the alkenyl groups bonded to the silicon atoms at both ends of the molecular chain is less than 3, at least one alkenyl group is bonded to the silicon atom that is not at the end (but in the middle) of the molecular chain (e.g., as a substituent in the diorganosiloxane unit). As described above, the viscosity of the linear organopolysiloxane is preferably 10 to 1000000 mPa·s at 25° C. in terms of workability and curability. Moreover, the linear organopolysiloxane may include a small amount of branched structure (trifunctional siloxane units) in the molecular chain.

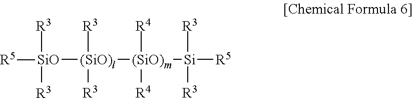

In the formula, R³ represents substituted or unsubstituted monovalent hydrocarbon groups that are the same as or different from each other, and at least one of them is an alkenyl group. R⁴ represents substituted or unsubstituted monovalent hydrocarbon groups that are the same as or different from each other and have no aliphatic unsaturated bond, R⁵ represents alkenyl groups, and l and m represent 0 or a positive integer. The monovalent hydrocarbon group represented by R³ preferably has 1 to 10 carbon atoms, and more preferably 1 to 6 carbon atoms. Specific examples of the monovalent hydrocarbon group include the following: alkyl groups such as methyl, ethyl, propyl, isopropyl, butyl, isobutyl, tert-butyl, pentyl, neopentyl, hexyl, cyclohexyl, octyl, nonyl, and decyl groups; aryl groups such as phenyl, tolyl, xylyl, and naphthyl groups; aralkyl groups such as benzyl, phenylethyl, and phenylpropyl groups; alkenyl groups such as vinyl, allyl, propenyl, isopropenyl, butenyl, hexenyl, cyclohexenyl, and octenyl groups; and substituted forms of these groups in which some or all hydrogen atoms are substituted by halogen atoms (fluorine, bromine, chlorine, etc.) or cyano groups, including halogen-substituted alkyl groups such as chloromethyl, chloropropyl, bromoethyl, and trifluoropropyl groups and cyanoethyl groups.

The monovalent hydrocarbon group represented by R⁴ also preferably has 1 to 10 carbon atoms, and more preferably 1 to 6 carbon atoms. Specific examples of the monovalent hydrocarbon group may be the same as those of R¹, but do not include an alkenyl group. The alkenyl group represented by R⁵ has, e.g., 2 to 6 carbon atoms, and more preferably 2 to 3 carbon atoms. Specific Examples of the alkenyl group may be the same as those of R² in the formula (Chemical Formula 5), and the vinyl group is preferred. In the formula (Chemical Formula 6), 1 and m are typically 0 or positive integers satisfying 0<l+m≤10000, preferably 5≤l+m≤2000, and more preferably 10≤l+m≤1200. Moreover, l and m are integers satisfying 0<l/(l+m)≤0.2, and preferably 0.0011≤l/(l+m)≤0.1.

(2) Crosslinking Component (Component A2)

The component A2 is an organohydrogenpolysiloxane that acts as a crosslinking agent. The addition reaction (hydrosilylation) between SiH groups in the component A2 and alkenyl groups in the component A1 produces a cured product. Any organohydrogenpolysiloxane that has two or more silicon-bonded hydrogen atoms (i.e., SiH groups) per molecule may be used. The molecular structure of the organohydrogenpolysiloxane may be a linear, ring, branched, or three-dimensional network structure. The number of silicon atoms in a molecule (i.e., the degree of polymerization) may be 2 to 1000, and particularly about 2 to 300.

The locations of the silicon atoms to which the hydrogen atoms are bonded are not particularly limited. The silicon atoms may be either at the ends or not at the ends (but in the middle) of the molecular chain. The silicon-bonded organic groups other than the hydrogen atoms may be, e.g., substituted or unsubstituted monovalent hydrocarbon groups that have no aliphatic unsaturated bond, which are the same as those of R¹ in the general formula (Chemical Formula 5).

The organohydrogenpolysiloxane of the component A2 may have the following structure.

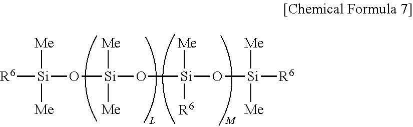

In the formula, R⁶'s are the same as or different from each other and represent alkyl groups, phenyl groups, epoxy groups, acryloyl groups, methacryloyl groups, alkoxy groups, or hydrogen atoms, and at least two of R⁶'s are hydrogen atoms. L represents an integer of 0 to 1000, and particularly 0 to 300, and M represents an integer of 1 to 200.

(3) Catalyst Component (Component C)

The catalyst component of the component C may be a catalyst used for a hydrosilylation reaction. Examples of the catalyst include platinum group metal catalysts such as platinum-based, palladium-based, and rhodium-based catalysts. The platinum-based catalysts include, e.g., platinum black, platinum chloride, chloroplatinic acid, a reaction product of chloroplatinic acid and monohydric alcohol, a complex of chloroplatinic acid and olefin or vinylsiloxane, and platinum bisacetoacetate.

(4) Thermally Conductive Inorganic Filler (Component B)

The thermally conductive inorganic filler is as described above.

(5) Other Additives

The composition of the present invention may include components other than the above as needed. For example, a heat resistance improver (such as colcothar, titanium oxide, or cerium oxide), a flame retardant auxiliary, and a curing retarder may be added. Moreover, an organic or inorganic pigment may be added for the purpose of coloring and toning.

### EXAMPLES

Hereinafter, the present invention will be described byway of examples. However, the present invention is not limited to the following examples. Various physical properties were measured in the following manner.

<Kinematic Viscosity>

The kinematic viscosity was measured at 25° C. using an Ubbelohde viscometer, and described in, e.g., the manufacturers catalog.

<BET Specific Surface Area>

The BET specific surface area of a thermally conductive filler was the value of the manufacturers catalog. The specific surface area means the surface area per unit mass or the surface area per unit volume of a substance. The specific surface area analysis is based on the adsorption of molecules on the surface of powder particles at a liquid nitrogen temperature. Since the area occupied by an adsorbed molecule has been known, the specific surface area of a sample is determined from the amount of the adsorbed molecules by using the BET equation.

<Average Particle Size>

The average particle size was D₅₀ (median diameter) in a volume-based cumulative particle size distribution measured by a laser diffraction scattering method. The method may use, e.g., a laser diffraction/scattering particle size distribution analyzer LA-950 S2 manufactured by HORIBA, Ltd.

<Shear Viscosity>

The shear viscosity was measured using a rheometer HAAKE MARS II (manufactured by Thermo Fisher Scientific KK) having parallel plates with a diameter (φ) of 20 mm under the conditions that the gap was 1.0 mm, the temperature was 23° C., and the shear rate was 1.0 (1/s).

<Thermal Conductivity of Thermally Conductive Grease and Thermally Conductive Silicone Sheet>

The thermal conductivity of thermally conductive grease and the thermal conductivity of a thermally conductive silicone sheet were measured at 25° C. using DynTIM (manufactured by Mentor Graphics Japan Co., Ltd.).

<Production of Thermally Conductive Grease Compound>

<Materials>

Examples and Comparative Examples used the following materials.

A. Matrix Resin (Base Oil)

(A-1) polydimethylsiloxane with trimethylsilyl at both ends: viscosity of 300 mm²/s

(A-2) poly(phenylmethyldimethyl)siloxane: viscosity of 125 mm²/s

B. Thermally Conductive Inorganic Filler

(B-1) fine powder α alumina: BET specific surface area of 6.7 m²/g, average particle size of 0.27 μm, X=24.815

(B-2) crushed α alumina: BET specific surface area of 5.2 m²/g, average particle size of 2.10 μm, X=2.476

(B-3) rounded aluminum nitride: BET specific surface area of 0.2 m²/g, average particle size of 20.0 μm, X=0.01

(B-4) spherical fused alumina: BET specific surface area of 0.2 m²/g, average particle size of 38.0 μm, X=0.005

C. First Surface Treatment Agent

(C-1) decyltrimethoxysilane: molecular weight of 262.5

(C-2) phenyltrimethoxysilane: molecular weight of 198.29

(C-3) methyltrimethoxysilane: molecular weight of 136.2

D. Second Surface Treatment Agent

(D-1) polydimethylsiloxane with vinyldimethylsilyl at both ends: viscosity of 350 mm²/s

(D-2)polydimethylsiloxane with trimethylsilyl at both ends: viscosity of 300 mm²/s

### Example 1

<First Surface Treatment of Thermally Conductive Inorganic Filler>

First, a dry surface treatment of 150.0 g of fine powder α alumina (B-1) (BET specific surface area (A_{BET}): 6.7 m²/g, average particle size (d₅₀): 0.27 μm, X=24.815) with 1.0 g of decyltrimethoxysilane (C-1) (molecular weight: 262.5), which was the first surface treatment agent, was performed by using Wonder Crusher WC-3 (manufactured by OSAKA CHEMICAL Co., Ltd.).

<Second Surface Treatment of Thermally Conductive Inorganic Filler>

Then, the thermally conductive inorganic filler that had been subjected to the first surface treatment was surface treated with 1.5 g of vinyldimethylsilyl-terminated polydimethylsiloxane (D-1) (viscosity: 350 mm²/s), which was the second surface treatment agent, by using Wonder Crusher WC-3 (manufactured by OSAKA CHEMICAL Co., Ltd.). The resulting inorganic filler was heat treated at 120° C. for 12 hours. Thus, the double surface treated thermally conductive inorganic filler was obtained.

<Production of Thermally Conductive Compound>

The thermally conductive inorganic filler prepared in the above manner and the matrix resin were mixed according to the composition shown in Table 1 by using a rotation-revolution mixer (MAZERUSTAR KK-400W manufactured by KURABO INDUSTRIES LTD.) to provide a thermally conductive compound.

### Examples 2 to 5, Comparative Examples 1 to 5

Examples 2 to 5 and Comparative Examples 1 to 5 were performed in the same manner as Example 1 except that the composition was varied as shown in Table 1. Table 1 shows the conditions and the results. The mass of each filler was expressed as the amount of charge (g) with respect to 100 g of the matrix resin

TABLE 1

| | | Comp. | | Comp. | | Comp. | | Comp. | | Comp. |
|---|---|---|---|---|---|---|---|---|---|---|
| | Ex. 1 | Ex. 1 | Ex. 2 | Ex. 2 | Ex. 3 | Ex. 3 | Ex. 4 | Ex. 4 | Ex. 5 | Ex. 5 |
| Matrix resin | A-1 | A-1 | A-1 | A-1 | A-1 | A-1 | A-2 | A-2 | A-1 | A-1 |
| mass (g) | 100 | 100 | 100 | 100 | 100 | 100 | 100 | 100 | 100 | 100 |
| Thermally conductive | B-1 | B-1 | B-1 | B-1 | B-2 | B-2 | B-2 | B-2 | B-3 | B-3 |
| inorganic filler | 322.6 | 313.4 | 484.0 | 473.3 | 492.2 | 496.7 | 492.2 | 496.7 | 527.6 | 497.0 |
| mass (g) | | | | | | | | | | |
| First surface | C-1 | C-1 | C-1 | C-1 | C-2 | None | C-2 | None | C-3 | C-3 |
| treatment agent | 7.3 | 7.1 | 10.9 | 10.65 | 4.60 | — | 4.60 | — | 3.21 | 3.00 |
| mass (g) | | | | | | | | | | |
| Second surface | D-1 | None | D-1 | None | D-2 | D-2 | D-2 | D-2 | D-1 | None |
| treatment agent | 3.23 | — | 4.85 | — | 3.30 | 3.30 | 3.30 | 3.30 | 5.25 | |
| mass (g) | | | | | | | | | | |
| Amount of first surface | 2.25 | 2.25 | 2.25 | 2.25 | 0.93 | None | 0.93 | None | 0.61 | 0.60 |
| treatment agent added | | | | | | | | | | |
| to filler (mass %) | | | | | | | | | | |
| Total amount of matrix | 103.2 | 100.0 | 104.9 | 100.0 | 103.3 | 103.3 | 103.3 | 103.3 | 105.3 | 100.0 |
| resin and second | | | | | | | | | | |
| surface treatment | | | | | | | | | | |
| agent (g) | | | | | | | | | | |
| Calculated value of | 75.8 | 75.8 | 82.2 | 82.6 | 82.7 | 82.8 | 82.7 | 82.8 | 83.4 | 83.2 |
| amount of thermally | | | | | | | | | | |
| conductive inorganic | | | | | | | | | | |
| filler added (mass %) | | | | | | | | | | |
| Shear viscosity | 510 | 731 | 1770 | 2470 | 279 | 966 | 1010 | 3500 | 332 | 427 |
| (Pa · s, 23° C.) | | | | | | | | | | |
| Thermal conductivity | 1.1 | 1.1 | 1.4 | 1.4 | 1.3 | 1.3 | 1.3 | 1.3 | 2.5 | 2.5 |
| (W/m · K) | | | | | | | | | | |

Comparing Examples 1, 2, 3, 4, and 5 with Comparative Examples 1, 2, 3, 4, and 5, respectively, the results confirmed that each of the thermally conductive compounds of Examples had a lower shear viscosity, so that the extrudability and the moldability were improved. This can be attributed to the advantage of the combination of the first surface treatment and the second surface treatment.

<Production of Thermally Conductive Silicone Sheet>

### Example 6

The matrix resin component (A) was a two-part heat curing silicone polymer. The two-part heat curing silicon polymer was composed of a component (A-3a) that previously contained a base polymer component and a platinum-based metal catalyst, and a component (A-3b) that previously contained abase polymer component and a crosslinking component. The thermally conductive inorganic filler was subjected to the first surface treatment and the second surface treatment in the same manner as Example 1. Table 2 shows the components and their amounts used for the surface treatments. The compounds obtained after the mixing process had shear viscosities of 1780 Pa·s and 1700 Pa·s at 23° C., respectively. These compounds were mixed, sandwiched between polyester (PET) films, and rolled into a sheet with a thickness of 2.0 mm. This sample was cured by heating at 100° C. for 15 minutes. Table 2 shows the hardness (Asker-C) and the thermal conductivity of the resulting thermally conductive silicone sheet.

### Comparative Example 6

According to the composition shown in Table 2, compounds of Comparative Example 6 were obtained in the same manner as Example 6. The shear viscosity was measured before curing the compounds. Then, a cured product was obtained by performing the same operation as that in Example. Table 2 shows the results of measuring the hardness and thermal conductivity of the cured product.

TABLE 2

| | | Ex. 6 | | Comp. Ex. 6 | |
|---|---|---|---|---|---|
| Matrix resin 1 | | A-3a | A-3b | A-3a | A-3b |
| mass (g) | | 100 | 100 | 100 | 100 |
| Matrix resin 2 | | None | None | A-1 | A-1 |
| mass (g) | | | | 6.0 | 6.0 |
| Thermally conductive | Thermally conductive inorganic filler | B-1 | B-1 | B-1 | B-1 |
| filler 1 | mass (g) | 193.6 | 193.6 | 195.6 | 195.6 |
| | First surface treatment agent | C-1 | C-1 | C-1 | C-1 |
| | mass (g) | 4.36 | 4.36 | 4.40 | 4.40 |
| | Second surface treatment agent | D-1 | D-1 | None | None |
| | mass (g) | 1.94 | 1.94 | — | — |
| Thermally conductive | Thermally conductive inorganic filler | B-2 | B-2 | B-2 | B-2 |
| filler 2 | mass (g) | 491.8 | 491.8 | 495.0 | 495.0 |
| | First surface treatment agent | C-1 | C-1 | C-1 | C-1 |
| | mass (g) | 4.90 | 4.90 | 4.95 | 4.95 |
| | Second surface treatment agent | D-2 | D-2 | None | None |
| | mass (g) | 3.30 | 3.30 | — | — |
| Thermally conductive | Thermally conductive inorganic filler | B-4 | B-4 | B-4 | B-4 |
| filler 3 | mass (g) | 200.0 | 200.0 | 200.0 | 200.0 |

| | | | | |
|---|---|---|---|---|
| Amount of first surface treatment agent added to filler (mass %) | 1.35 | 1.35 | 1.35 | 1.35 |
| Total amount of matrix resin and second surface treatment agent (g) | 105.2 | 105.2 | 106.0 | 106.0 |
| Calculated value of content of thermally conductive filler | 89.4 | 89.4 | 89.4 | 89.4 |
| (1 + 2 + 3) (mass %) | | | | |
| Shear viscosity (Pa · s, 23° C.) | 1780 | 1700 | 1930 | 1910 |

| | | |
|---|---|---|
| Hardness (Asker-C) after 10 seconds | 9 | 6 |
| Thermal conductivity (W/m · K) | 2.8 | 2.8 |

As shown in Table 2, the cured products of Example 6 and Comparative Example 6 were approximately the same in hardness and thermal conductivity. However, the shear viscosity of the composition before curing in Example 6 was lower than that of the composition before curing in Comparative Example 6. Consequently, the composition of Example 6 had high extrudability and high moldability. On the other hand, the composition of Comparative Example 6 bad not been subjected to the second surface treatment and thus had a high shear viscosity, which resulted in low extrudability and low moldability.

### INDUSTRIAL APPLICABILITY

The thermally conductive silicone composition of the present invention is suitable as a thermal interface material (TIM) to be interposed between a heat generating member and a heat dissipating material of electrical and electronic components or the like.

1. A thermally conductive silicone composition comprising:
a silicone polymer as a matrix resin; and
a thermally conductive inorganic filler,
wherein the thermally conductive inorganic filler is surface treated with a first surface treatment agent and further surface treated with a second surface treatment agent,
the surface treatment with the first surface treatment agent and the surface treatment with the second surface treatment agent are performed before the silicone polymer as the matrix resin and the thermally conductive inorganic filler are mixed to form the composition,
the first surface treatment agent and the second surface treatment agent are fixed to a surface of the thermally conductive inorganic filler by heating,
the first surface treatment agent contains an organic silane compound represented by R¹¹SiR¹²ₓ(OR¹³)₃₋ₓ (where R¹¹ is a monovalent aliphatic hydrocarbon group having 1 to 18 carbon atoms, a monovalent aromatic hydrocarbon group having 6 to 30 carbon atoms, or a monovalent substituent represented by the following Chemical Formula (1), Chemical Formula (2), Chemical Formula (3), or Chemical Formula (4):
R¹⁴_{y}R¹⁵_{3-y}SiOR¹⁶(CₙH₂ₙ)ₚ (1);
[(R¹³O)_{3-z}R¹²_{z}Si](CₙH₂ₙ)ₚR¹⁶(CₙH₂ₙ)ₚ (2);
[(R¹³O)_{3-z}R¹²_{z}SiO]R¹⁶ (3);
[(R¹³O)_{3-z}R¹²_{z}Si]R¹⁷ (4),
R¹² is a methyl group or a phenyl group and may be the same or different,
R¹³ is a hydrocarbon group having 1 to 4 carbon atoms and may be the same or different,
R¹⁴ is a hydrocarbon group having 1 to 4 carbon atoms or a phenyl group and may include a double bond,
R¹⁵ is a methyl group or a phenyl group,
R¹⁶ is a divalent polysiloxane represented by (R¹⁸₂SiO)ₘ,
R¹⁷ is a divalent aliphatic hydrocarbon group having 1 to 18 carbon atoms or a divalent aromatic hydrocarbon group having 6 to 30 carbon atoms,
R¹⁸ is at least one selected from the group consisting of a methyl group and a phenyl group, x is 0 to 2, y is 1 to 3, z is 0 to 3, n is an integer of 1 to 4, m is an integer of 1 to 20, and p is 0 or 1), and
the second surface treatment agent contains a silicone polymer that has a kinematic viscosity of 10 to 1000 mm²/s and does not have a hydrolyzable group.

2. The thermally conductive silicone composition according to claim 1, wherein a content of the thermally conductive inorganic filler that has been surface treated with the first surface treatment agent and the second surface treatment agent is 100 to 10000 parts by mass with respect to 100 parts by mass of the silicone polymer as the matrix resin.

3. The thermally conductive silicone composition according to claim 1, wherein the first surface treatment agent is applied in an amount of 0.1 to 50 parts by mass with respect to 100 parts by mass of the thermally conductive inorganic filler.

4. The thermally conductive silicone composition according to claim 1, wherein the second surface treatment agent is applied in an amount of 0.1 to 50 parts by mass with respect to 100 parts by mass of the thermally conductive inorganic filler.

5. The thermally conductive silicone composition according to claim 1, wherein the thermally conductive inorganic filler is composed of inorganic particles of at least one selected from the group consisting of aluminum oxide, zinc oxide, magnesium oxide, aluminum nitride, boron nitride, and aluminum hydroxide.

6. The thermally conductive silicone composition according to claim 1, wherein the thermally conductive silicone composition is in the form of at least one selected from the group consisting of grease, putty, gel, and rubber.

7. A method for producing a thermally conductive silicone composition comprising a silicone polymer as a matrix resin and a thermally conductive inorganic filler,
the method comprising:
performing a first surface treatment of the thermally conductive inorganic filler with a first surface treatment agent;
performing a second surface treatment of the thermally conductive inorganic filler with a second surface treatment agent;
fixing the first surface treatment agent and the second surface treatment agent to a surface of the thermally conductive inorganic filler by heating; and then
mixing the silicone polymer as the matrix resin and the thermally conductive inorganic filler that has been subjected to the first surface treatment and the second surface treatment, and optionally curing the mixture,
wherein the first surface treatment agent contains an organic silane compound represented by R¹¹SiR¹²ₓ(OR¹³)₃₋ₓ (where R¹¹ is a monovalent aliphatic hydrocarbon group having 1 to 18 carbon atoms, a monovalent aromatic hydrocarbon group having 6 to 30 carbon atoms, or a monovalent substituent represented by the following Chemical Formula (1), Chemical Formula (2), Chemical Formula (3), or Chemical Formula (4):
R¹⁴_{y}R¹⁵_{3-y}SiOR¹⁶(CₙH₂ₙ)ₚ (1);
[(R¹³O)_{3-z}R¹²_{z}Si](CₙH₂ₙ)ₚR¹⁶(CₙH₂ₙ)ₚ (2);
[(R¹³O)_{3-z}R¹²_{z}SiO]R¹⁶ (3);
[(R¹³O)_{3-z}R¹²_{z}Si]R¹⁷ (4),
R¹² is a methyl group or a phenyl group and may be the same or different,
R¹³ is a hydrocarbon group having 1 to 4 carbon atoms and may be the same or different,
R¹⁴ is a hydrocarbon group having 1 to 4 carbon atoms or a phenyl group and may include a double bond,
R¹⁵ is a methyl group or a phenyl group,
R¹⁶ is a divalent polysiloxane represented by (R¹⁸₂SiO)ₘ,
R¹⁷ is a divalent aliphatic hydrocarbon group having 1 to 18 carbon atoms or a divalent aromatic hydrocarbon group having 6 to 30 carbon atoms,
R¹⁸ is at least one selected from the group consisting of a methyl group and a phenyl group,
x is 0 to 2, y is 1 to 3, z is 0 to 3, n is an integer of 1 to 4, m is an integer of 1 to 20, and p is 0 or 1), and
the second surface treatment agent contains a silicone polymer that has a kinematic viscosity of 10 to 1000 mm²/s and does not have a hydrolyzable group.

8. The method according to claim 7, wherein the curing is carried out, the method further comprising a molding process between the mixing process and the curing process.

9. The method according to claim 7, wherein the process using the first surface treatment agent includes a heating process at 80 to 180° C. for 1 to 24 hours, and further the process using the second surface treatment agent includes a heating process at 80 to 180° C. for 1 to 24 hours.
